(19) United States
(12) Patent Application Publication
(10) Pub. No.: US 2026/0223483 A1
(43) Pub. Date: Jul. 30, 2026

(54) PHOTODETECTOR AND MANUFACTURING METHOD THEREOF

(71) Applicant: Taiwan Nano & Micro-Photonics Co., Ltd., Taipei City (TW)

(72) Inventors: Ching-Fuh Lin, Taipei (TW); Hsiang-Fu Li, Taipei City (TW); Jing-Ting Hung, Taipei City (TW)

(21) Appl. No.: 19/263,487

(22) Filed: Jul. 9, 2025

Related U.S. Application Data
(60) Provisional application No. 63/749,005, filed on Jan. 24, 2025.

(51) Int. Cl. H10F 77/30

(52) U.S. Cl. CPC H10F 77/331

(57) ABSTRACT

This invention provides highly sensitive optical photodetectors utilizing advanced silicon photonics, metal nano-film, and passivation layer technologies for superior optical detection. A photodetector for detecting an incident light is provided with a semiconductor substrate, a metal nano-film, and a first passivation layer. The metal nano-film comprises nanoparticles or nanostructures in Schottky contact of a first surface of the semiconductor substrate, and the first passivation layer covers the nanoparticles or nanostructures of the metal nano-film.

### CROSS-REFERENCE TO RELATED APPLICATIONS

This application claims the priority of U.S. Provisional Patent Application No. 63/749,005 filed on Jan. 24, 2025. This application and all published documents discussed below are fully incorporated by reference as if fully set forth herein.

### BACKGROUND OF THE INVENTION

### 1. Field of the Invention

The present invention relates to photodetectors and their manufacturing method.

### 2. Description of Related Art

U.S. Pat. No. 10,734,539B2 discloses a Schottky barrier photodetector with a metal-semiconductor junction for measuring infrared radiation. To enhance the electric fields and optical absorption, the surface of semiconductor may include micro-structures to induce localized surface plasmon resonance at the metal-semiconductor junction stimulated by incident light.

Schottky barrier photodetectors are highly sensitive and fast responsive compared to other heterojunction devices. The properties of Schottky barrier photodetector are mainly dependent on the junction properties.

On the other hand, as a result of light reflection and absorption in the metal layer, Schottky photodiodes are typically less effective than PIN photodiodes at longer wavelengths. Further development is being continuously pursued to improve the performance. A need is arisen for an improved photodetector that includes enhanced performance and improved stability.

### SUMMARY OF THE INVENTION

This summary is provided to introduce a selection of concepts in a simplified form that are further described below in the detailed description. This summary, and the foregoing background, is not intended to identify key aspects or essential aspects of the claimed subject matter. Moreover, this summary is not intended for use as an aid in determining the scope of the claimed subject matter.

This invention presents a highly sensitive optical sensor utilizing advanced silicon photonics, metal nano-film, and passivation layer technologies for superior optical detection. The core consists of:

Silicon photonics: enhances light absorption and propagation control, boosting sensitivity to small changes.

Metal nano-film: strengthens the local electric field, improving signal intensity and precision.

Passivation layer: protects from environmental factors while optimizing signal response. The passivation layer introduced into the metal nanoparticles/nanostructures effectively protects them from forming compounds and degrading, stabilizes their morphology, and minimizes the impact of environmental fluctuations.

Together, these technologies allow the inventive photodetectors with exceptional sensitivity, strong interference resistance, and long-term stability, ideal for high-precision applications.

In one aspect, a photodetector for detecting an incident light is provided with a semiconductor substrate, a metal nano-film, a first electrode, a second electrode, and a first passivation layer. The semiconductor substrate includes a first surface and a second surface. The metal nano-film comprises nanoparticles or nanostructures in Schottky contact of the first surface of the semiconductor substrate. The first electrode is in contact of the first surface of the semiconductor substrate. The second electrode is in contact of the second surface of semiconductor substrate. The first passivation layer covers the nanoparticles or nanostructures of the metal nano-film.

Additional features of the invention are set out in the appended set of claims.

This innovation ensures consistent photodetector performance during operation and storage, while also enabling compatibility with mature CMOS processes. The challenge of balancing optical and electrical properties after the introduction of the passivation layer has been overcome, leading to a highly stable and high-performance photodetector.

### BRIEF DESCRIPTION OF THE DRAWINGS

Non-limiting and non-exhaustive embodiments of the disclosed technology, including the preferred embodiment, are described with reference to the following figures, wherein like reference numerals refer to like parts throughout the various views unless otherwise specified.

FIG. 1 is a cross-sectional view showing a photodetector in accordance with an embodiment of the present invention.

FIG. 2 is a partially side view showing a photodetector in accordance with an embodiment of the present invention.

FIG. 3A shows a method for forming metal nanoparticles in accordance with an embodiment of the present invention.

FIG. 3B are scanning electron microscope (SEM) images showing morphologies of metal nanoparticles formed by the method described in FIG. 3A using different annealing temperatures and times.

FIGS. 4A-4D are schematic top views showing that the metal nano-film is patterned to form an inverted cross array, a cross, a grid array (a square hole array), and a block array (a square array), respectively, in accordance with some embodiments of this invention.

FIG. 5A shows a method for forming a metasurface in accordance with an embodiment of the present invention.

FIG. 5B shows a method for forming a metasurface in accordance with an embodiment of the present invention.

FIG. 6 shows a method for depositing a passivation layer to cover metal nanoparticles in accordance with an embodiment of the present invention.

FIG. 7A shows a method for depositing a multi-layered passivation layer to cover metal nanoparticles in accordance with an embodiment of the present invention.

FIG. 7B shows a method for depositing a multi-layered passivation layer to cover the surface of metal-nano film in accordance with an embodiment of the present invention.

FIG. 8 is a schematic view showing a function of the inventive passivation layer.

FIG. 9 is schematic side view showing a semiconductor substrate in accordance with an embodiment of this invention.

FIG. 10 is a partially enlarged schematic view showing a semiconductor substrate in accordance with an embodiment of this invention.

FIG. 11 is a partially enlarged schematic view showing a semiconductor substrate in accordance with an embodiment of this invention.

FIG. 12 shows response current-time graphs of one inventive photodetector with a passivation layer (w/PSV) fabricated by the one-step process and a comparative sample without the passivation layer (w/o PSV).

FIG. 13 shows IV curves of one inventive photodetector with a passivation layer and a comparative sample without the passivation layer.

FIG. 14 are photographs and schematic diagrams showing that surfaces of two semiconductor substrates are modified into a hydrophobic surface and a hydrophilic surface, respectively.

### DETAILED DESCRIPTION OF THE PREFERRED EMBODIMENT

Embodiments are described more fully below with reference to the accompanying Figures, which form a part hereof and show, by way of illustration, specific exemplary embodiments. These embodiments are disclosed in sufficient detail to enable those skilled in the art to practice the invention. However, embodiments may be implemented in many different forms and should not be construed as being limited to the embodiments set forth herein. The following detailed description is, therefore, not to be taken in a limiting sense.

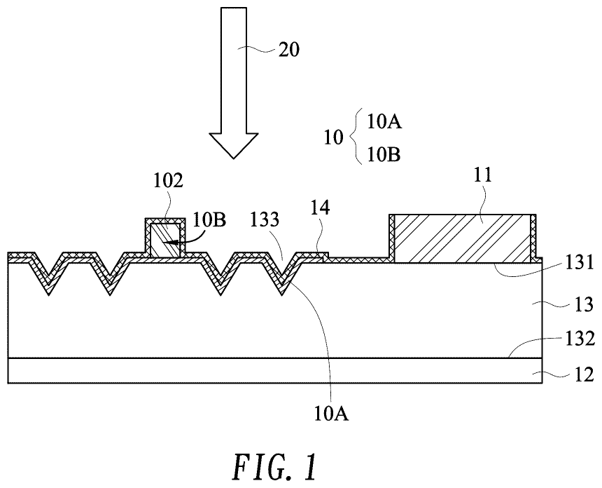

FIG. 1 is a cross-sectional view showing a photodetector in accordance with an embodiment of the present invention. Referring to FIG. 1, the photodetector is used to detect an incident light 20 and typically includes a semiconductor substrate 13, a metal nano-film 10, a first electrode 11, a second electrode 12, and a passivation layer 14. In the exemplary embodiment, the semiconductor substrate 13 is an n-type silicon substrate having a first surface 131 and a second surface 132. Other semiconductor materials, n-type or p-type, e.g., gallium and germanium, may be used. The metal nano-film 10 consists of a first metal nano-film 10A and a second metal nano-film 10B, which is patterned to form a metasurface composed of a plasmonic nanostructure array 102. The first metal nano-film 10A is deposited on and in Schottky contact of the first surface 131 of the semiconductor substrate 13. The first metal nano-film 10A could be made of Ag, Au, Pt, etc. The plasmonic nanostructure array 102, made of Ag, Au, Pt, etc, is deposited on the first metal nano-film 10A. The first electrode 11 is generally deposited on the first surface of the semiconductor substrate 13 and electrically connected to the plasmonic nanostructure array 102, and the second electrode 12 is generally deposited on the second surface of semiconductor substrate 13. In addition, the passivation layer 14 covers the metal nano-film 10 and may further cover the first electrode 11.

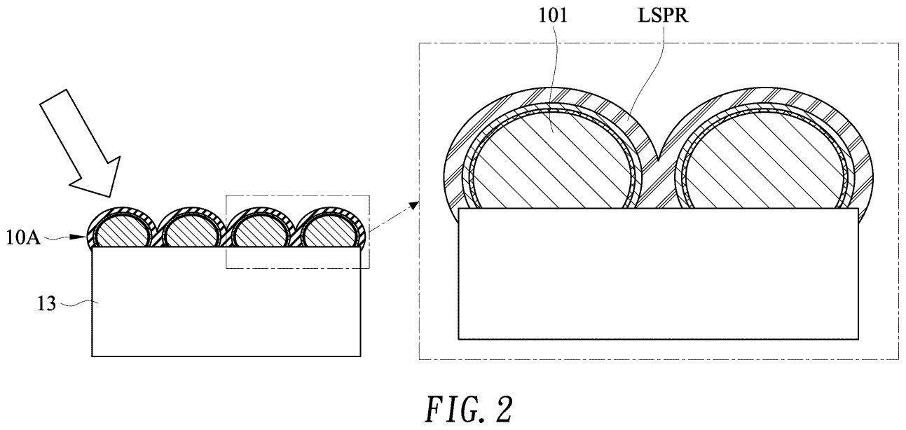

FIG. 2 is a partially side view showing a photodetector in accordance with another embodiment of the present invention. The photodetector described in FIG. 2 is similar to the photodetector described in FIG. 1, except as described below. Referring to FIG. 2, in some embodiments, the metal nano-film 10 only includes the first metal nano-film 10A and does not include the second metal nano-film 10B. The first metal nano-film 10A includes metal nanoparticles 101 to reduce reflectivity of the incident light and/or to induce localized surface plasmon resonance (LSPR) by interaction between the metal nanoparticles and the incident light. In such an embodiment, the passivation layer 14 may cover the metal nanoparticles 101 and exposed surfaces of the semiconductor substrate 13 between the metal nanoparticles 101.

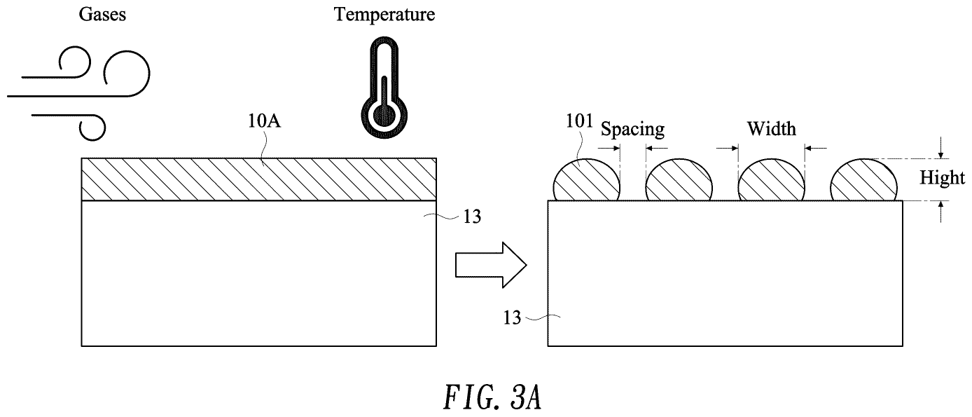

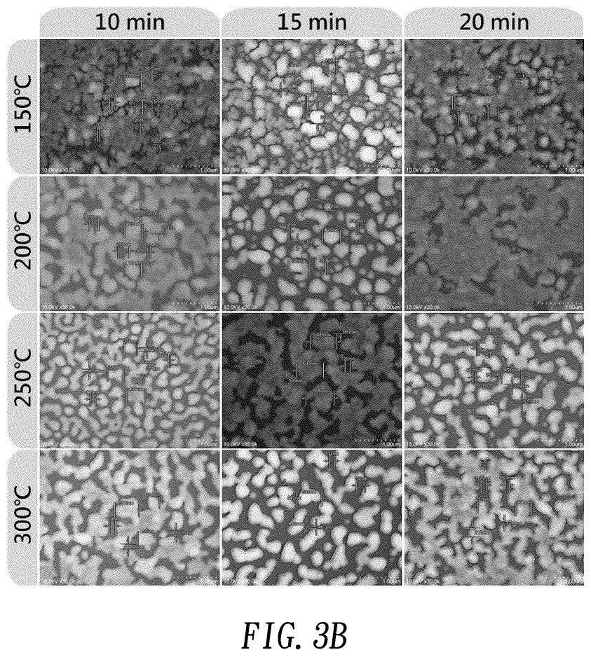

FIG. 3A shows a method for forming the metal nanoparticles 101 in accordance with an embodiment of the present invention. Referring to FIG. 3A, a first metal nano-film 10A is firstly deposited on the first surface 131 of the semiconductor substrate via a suitable manner, e.g., physical vapor deposition (PVD), such as sputtering. Then the first metal nano-film 10A is transformed to metal nanoparticles 101 by an annealing process, such as rapid thermal annealing (RTA), furnace annealing, laser annealing, etc., in a gas environment, e.g., in a chamber or device containing at least a gas. The morphology of metal nanoparticles 101 could be adjusted by one or more parameters of the annealing process, e.g., temperature, pressure, gas flow rate, annealing time, thermal profile, and type of gases (e.g., N₂, H₂, Ar, etc.).

FIG. 3B are scanning electron microscope (SEM) images showing morphologies of metal nanoparticles formed by the method described in FIG. 3A using different annealing temperatures and annealing times.

In some embodiments, the first metal-nano film 10 consists of metal nanoparticles 101 with surface morphology characterized by three key parameters: height, width, and spacing, as depicted in FIG. 3A. For enabling light to penetrate the metal, the height (vertical Feret diameter) of metal nanoparticles 101 is between about 10 nm and about 50 nm. To induce LSPR by interaction between the incident light and the metal nanoparticles, the width (horizontal Feret diameter) of metal nanoparticles 101 is between about 5 nm and about 500 nm. To facilitate the quantum tunneling effect that ensures smooth electronic signal transmission, the spacing (the minimum distance between two parallel planes restricting two adjacent metal nanoparticles 101 perpendicular to the horizontal direction) between metal nanoparticles 101 is between about 0.5 nm and about 50 nm.

Referring to FIG. 1, in some embodiments, the metal nano-film 10 only includes the first metal nano-film 10A and does not include the second metal nano-film 10B, and the first metal nano-film 10A is patterned to form the metasurface comprising the plasmonic nanostructure array 102 with sub-wavelength periodicity for inducing localized surface plasmon resonance (LSPR). In such an embodiment, the plasmonic nanostructure array 102 is deposited on the first surface 131 of the semiconductor substrate 13 and the passivation layer covers the plasmonic nanostructure array 102.

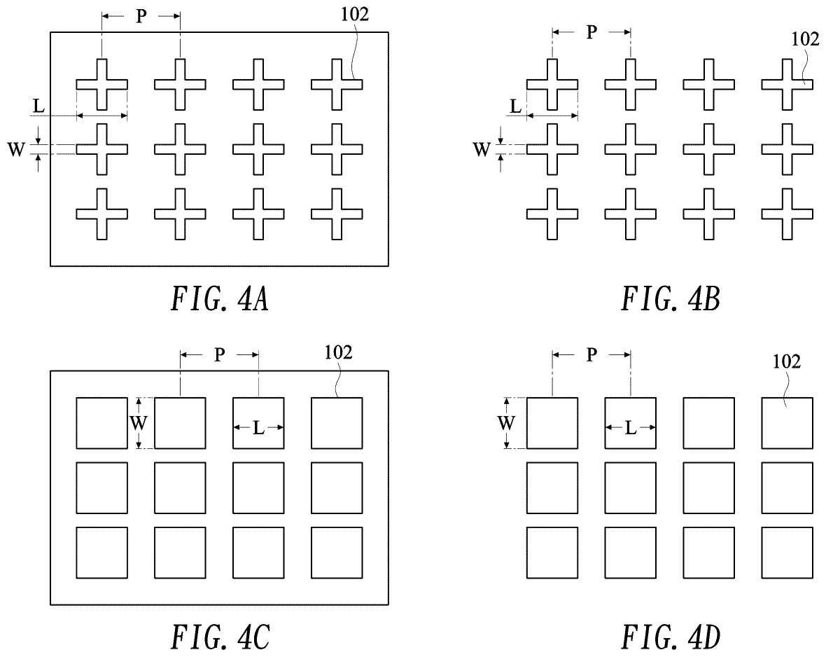

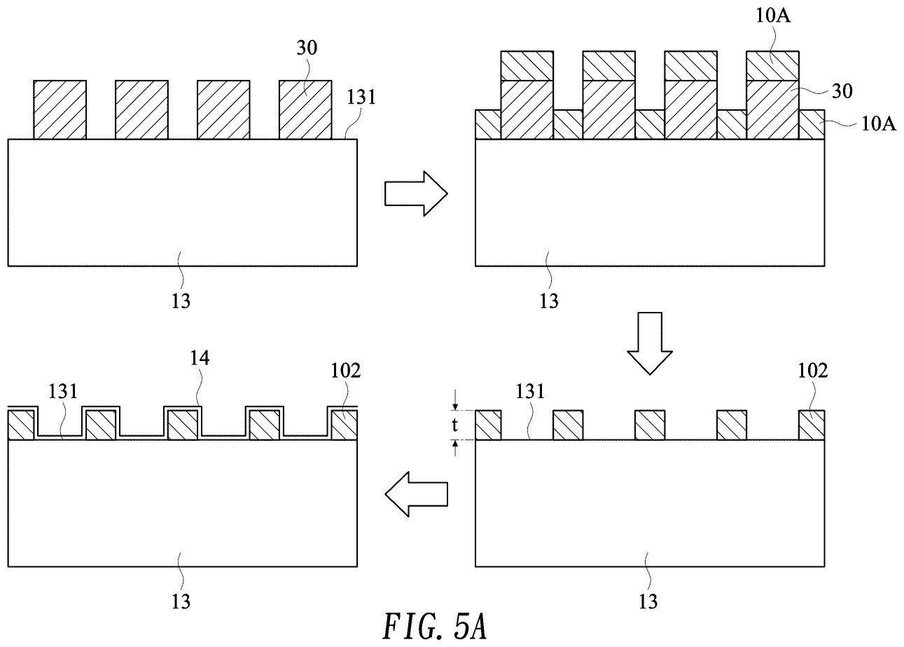

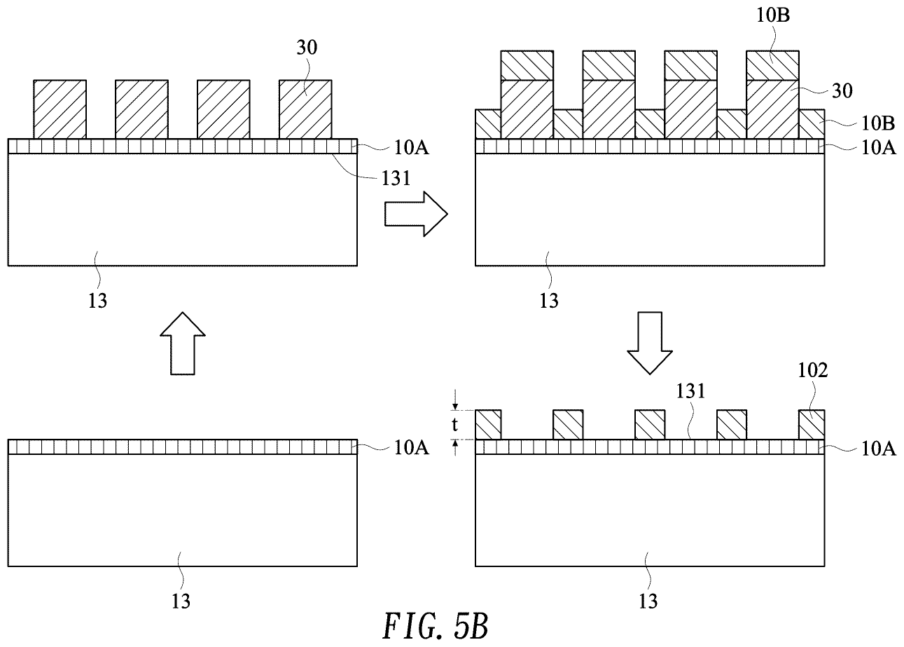

FIGS. 4A-4D are schematic top views showing that the plasmonic nanostructure array 102 could be an inverted cross array, a cross array, a grid array (a square hole array), and a block array (a square array), respectively, in accordance with some embodiments of this invention. The plasmonic nanostructure array 102 is deposited on the first metal nano-film 10A (FIG. 1) or deposited on the first surface 131 of the semiconductor substrate 13 by patterning the first metal nano-film 10A (will be described in FIG. 5).

Referring to FIGS. 4A-4D, one or more resonant wavelengths of the surface plasmon resonance and electromagnetic properties could be determined by one or more geometric parameters of the plasmonic nanostructure array 102. As illustrated in FIGS. 4A-4D, the one or more geometric parameters typically include a width, a length, a period, and a thickness of patterns composing the plasmonic nanostructure array.

Referring to FIG. 4B, the plasmonic nanostructure array 102 is a cross array. Each cross pattern is composed of an upright section traversed by a horizontal one. The dimensions “width (W)” and “length (L)” are respectively defined as the width and the length of the horizontal or upright section, and the period (P) is the center-to-center distance between two adjacent cross patterns.

In one example, the photodetector is used to detect an incident light comprising mid-wave infrared (MWIR) light. In such applications, the plasmonic nanostructure array 102 could be a cross array made of Ag, Au, Cu, or other plasmonic materials, in which the thickness of the plasmonic nanostructure array 102 is between about 200 nm and about 600 nm, the width is between about 0.2 μm and about 2.5 μm, the length is between about 0.8 μm and about 3.5 μm, and the period is between about 1.5 μm and about 4.0 μm.

Referring to FIG. 4A, the plasmonic nanostructure array 102 is an inverted cross array. Each inverted cross (cavity) is composed of an upright section traversed by a horizontal one. The dimensions “width (W)” and “length (L)” are respectively defined as the width and the length of the horizontal or upright section, and the period (P) is the center-to-center distance between two adjacent inverted cross patterns.

In one example, the photodetector is used to detect an incident light comprising mid-wave infrared (MWIR) light. In such applications, the plasmonic nanostructure array 102 could be an inverted cross array made of Ag, Au, Cu, or other plasmonic materials, in which the thickness of the plasmonic nanostructure array is between about 200 nm and about 600 nm, the width (W) is between about 1.0 μm and about 4.0 μm, the length (L) is between about 0.2 μm and about 6.0 μm, and the period (P) is between about 1.5 μm and about 8.0 μm.

Referring to FIG. 4D, the plasmonic nanostructure array 102 is a square array (block array). The dimensions “width (W)” and “length (L)” are respectively defined as the width and the length of a single square, and the period (P) is the center-to-center distance between two adjacent square patterns.

In one example, the photodetector is used to detect an incident light comprising mid-wave infrared (MWIR) light. In such applications, the plasmonic nanostructure array 102 could be a square array made of Ag, Au, Cu, or other plasmonic materials, in which the thickness of the plasmonic nanostructure array 102 is between about 200 nm and about 600 nm, the width (W)/length (L) is between about 1.0 μm and about 6.0 μm, and the period (P) is between about 1.5 μm and about 8.0 μm.

Referring to FIG. 4C, the plasmonic nanostructure array 102 is a square hole array (grid array). The dimensions “width (W)” and “length (L)” are respectively defined as the width and the length of a single square hole, and the period (P) is the center-to-center distance between two adjacent square hole patterns.

In one example, the photodetector is used to detect an incident light comprising mid-wave infrared (MWIR) light. In such applications, the plasmonic nanostructure array 102 could be a square hole array made of Ag, Au, Cu, or other plasmonic materials, in which the thickness of the plasmonic nanostructure array 102 is between about 200 nm and about 600 nm, the width (W)/length (L) is between about 0.8 μm and about 5.0 μm, and the period is between about 1.5 μm and about 8.0 μm.

The metasurface is preferably completed through a complementary oxide semiconductor (CMOS) process, such as lift-off technology, etching, nano-printing, laser writing, etc.

FIG. 5A shows a method for forming a metasurface in accordance with an embodiment of the present invention. Referring to FIG. 5A, the method mainly includes the step of: (1) depositing a photoresist layer on the first surface 131 of the semiconductor substrate 13 and patterning the photoresist layer to form a patterned photoresist layer 30; (2) depositing a first metal nano-film 10A to cover the patterned photoresist layer 30 and exposed surfaces of the semiconductor substrate 13; and (3) removing the patterned photoresist layer 30 to form the metasurface composed of the plasmonic nanostructure array 102. In addition, the method may further include a step of depositing a passivation layer 14 to cover the metasurface composed of the plasmonic nanostructure array 102.

FIG. 5B shows a method for forming a metasurface presented in FIG. 1. Referring to FIG. 5B, the method may include the steps of: (1) depositing a first metal nano-film 10A on the first surface 131 of the semiconductor substrate 13; (2) depositing a photoresist layer on the first metal nano-film 10A and patterning the photoresist layer to form a patterned photoresist layer 30 on the first metal nano-film 10A; (2) depositing a second metal nano-film 10B to cover the patterned photoresist layer 30 and exposed surfaces of the first metal nano-film 10A; and (3) removing the patterned photoresist layer 30 to form a metasurface composed of a plasmonic nanostructure array 102 on the first metal nano-film 10A. In some embodiments, the first metal nano film 10A and the plasmonic nanostructure array 102 are made of different metals. In some embodiments, the first metal nano film 10A and the plasmonic nanostructure array 102 are made of a same metal.

Referring to FIGS. 1 and 2, an object of the passivation layer 14 is used to protect the metal nanoparticles 101 or the metasurface comprising a plasmonic nanostructure array 102 as depicted in FIGS. 4A-4D. The performance of metal nano-film deteriorates rapidly under environmental factors such as temperature and humidity. Metal nano-film, composed of metal nanoparticles or nanostructure array, is prone to forming compounds and degrading in harsh environments. Over time, these metal nanoparticles or nanostructures may agglomerate and deform, thereby shortening their storage life under ambient conditions. Furthermore, temperature fluctuations during processing and operation can cause structural deformation, further impacting the performance of device.

The passivation layer 14 could be deposited via a one-step process or a two-step process in a gas environment, e.g., in a chamber or device containing at least a gas.

### One-Step Process

The one-step deposition process is divided into three stages: (1) preheating; (2) deposition; and (3) purge. These three stages can be completed in a same system or equipment.

### (1) Preheating:

A first metal nano-film 10A can be deposited on the first surface of the semiconductor substrate by, e.g., physical vapor deposition (PVD), such as sputtering. Then the first metal nano-film 10A is preheated with a temperature carefully maintained between about 200° C. and about 300° C. for 1 to 10 minutes. Preferably the preheating stage adopts the annealing process (200-300° C.) as described in FIG. 3 to transform the first metal nano-film 10A into metal nanoparticles 101. This stage is critical in shaping the morphology of the resulted metal particles, as it prevents excessive heat buildup that could lead to severe agglomeration of metal nanoparticles and the spacing between metal nanoparticles can be controlled between 0.5 nm and 50 nm.

In the case of the metal nano-film 10 including a metasurface, the preheating stage is unnecessary.

### (2) Deposition:

In some embodiments, the passivation layer includes a first passivation layer, which comprises an oxide layer, a nitride layer, or a dielectric layer comprising ZnS, Teflon, or MgF₂. The first passivation layer can be deposited using physical vapor deposition (PVD), chemical vapor deposition (CVD), or atomic layer deposition (ALD).

The physical vapor deposition (PVD) includes thermal evaporation, E-beam evaporation, RF sputtering, magnetron sputtering, reactive sputtering, high-power impulse magnetron sputtering (HiPIMS), etc.

The chemical vapor deposition (CVD) includes plasma-enhanced CVD (PECVD), atmospheric pressure CVD (APCVD), low-pressure CVD (LPCVD), hybrid physical-chemical vapor deposition (HPCVD), molecular beam epitaxy-CVD (MBE-CVD), etc.

The atomic layer deposition (ALD) includes thermal ALD, plasma-enhanced atomic layer deposition (PEALD), pulsed laser-assisted ALD, etc.

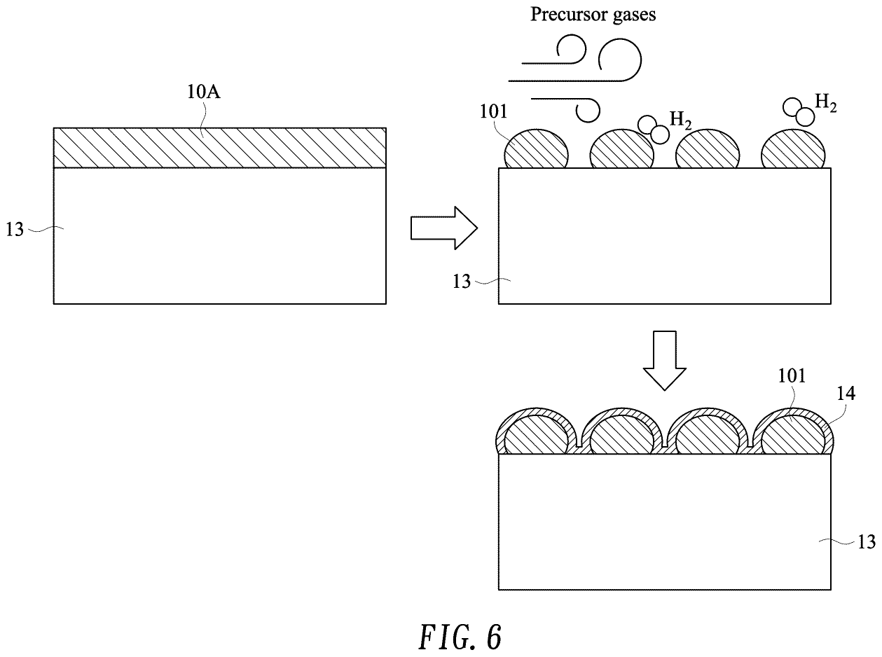

FIG. 6 shows a method for transforming the first metal-nano film 10A into metal nanoparticles 101 and depositing a passivation layer 14 to cover metal nanoparticles 101 in accordance with an embodiment of the present invention. The passivation layer 14 is preferably deposited in an oxygen-free environment, e.g., in a chamber or device containing at least a gas. In some embodiment, the at least a gas includes precursor gases and may include hydrogen. Alternatively, the hydrogen may be a reaction product of the precursor gases (e.g., silane). The presence of H₂ is essential during the deposition because H₂ helps clean the metal surface and ensures that the metal nanoparticles 101 maintain optimal activity.

The preheating and deposition stages are preferably performed by a chemical vapor deposition (CVD) system. During the preheating and deposition stages, process parameters, e.g., gas type, gas flow rate, pressure, temperature, time, etc., are controlled to not only transform the metal-nano film into the metal nanoparticles and to deposit the passivation layer on the metal nanoparticles in one-step and but also improve the optical properties of the metal nano-film, e.g., increasing transmittance and/or reducing reflectivity of the first metal-nano film composed of metal nanoparticles.

By controlling the process parameters, the thickness of the passivation layer, which stabilizes and fixes the surface morphology of metal nanoparticles or metasurface, is between about 30 nm and about 200 nm. Passivation layer that is too thick may increase absorption of light.

### Example of FIG. 6:

A plasma-enhanced CVD system is used to transform a first metal-nano film, e.g., a silver-nano film, into metal nanoparticles and depositing a SiO₂ passivation layer to cover metal nanoparticles. Table 1 lists precursor gases and process parameters used in the preheating and deposition process.

TABLE 1

| | |
|---|---|
| Temperature (° C.) | 150~300 |
| Pressure (mTorr) | 700~1200 |
| Flow rate of N₂O (sccm) | 650~900 |
| Flow rate of SiH₄ (sccm) | 6~15 |

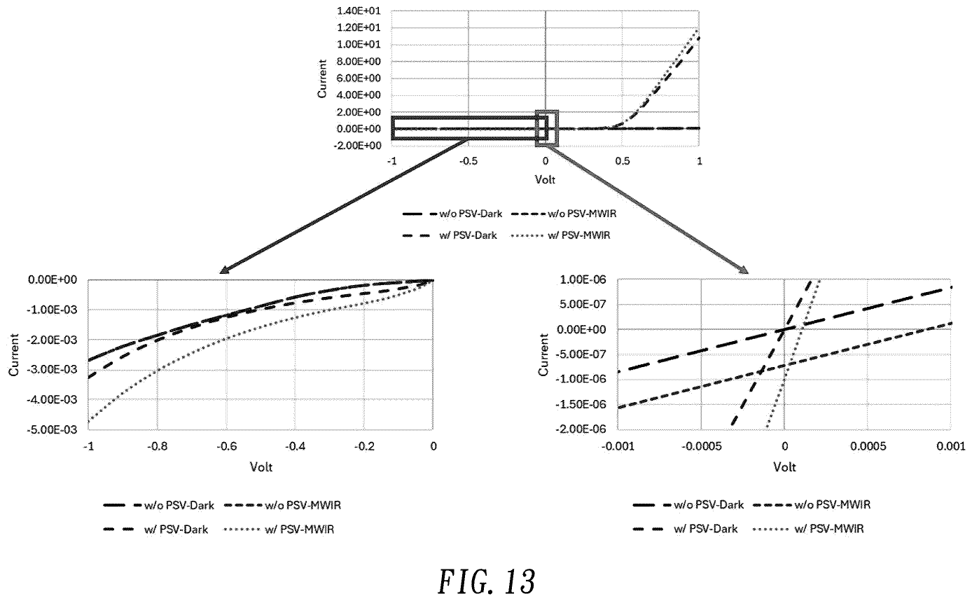

FIG. 13 shows IV curves of one inventive photodetector with a passivation layer and a compared sample without the passivation layer, wherein “dark” denotes that the photodetector is without light irradiation, and “MWIR” denotes that the photodetector is irradiated with mid-infrared light.

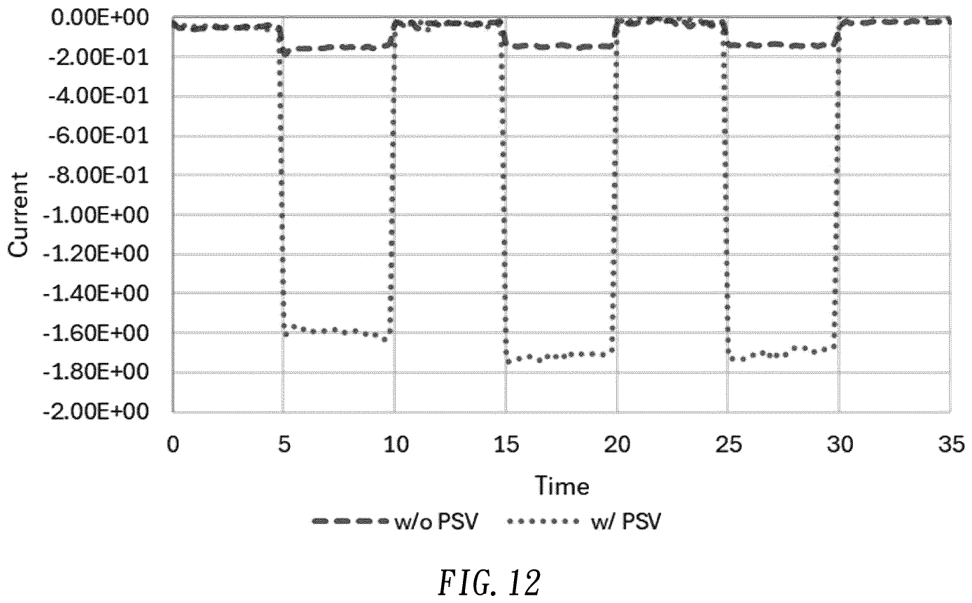

FIG. 12 shows current-time graphs of one inventive photodetector with a passivation layer (w/PSV) fabricated by the one-step process as described above and a compared sample without the passivation layer (w/o PSV), wherein a chopper (electronic switch) is used to periodically interrupt the light irradiation. As shown in FIG. 12, the response current of the photodetector modified by the one-step process is significantly improved.

### (3) Purge:

Residual gas or impurities are removed from the system to provide a clean and stable environment for subsequent processes.

### Two-Step Process

In some embodiments, the passivation layer includes a first passivation layer covering the metal nanoparticles or metasurface and a second passivation layer covering the first passivation layer.

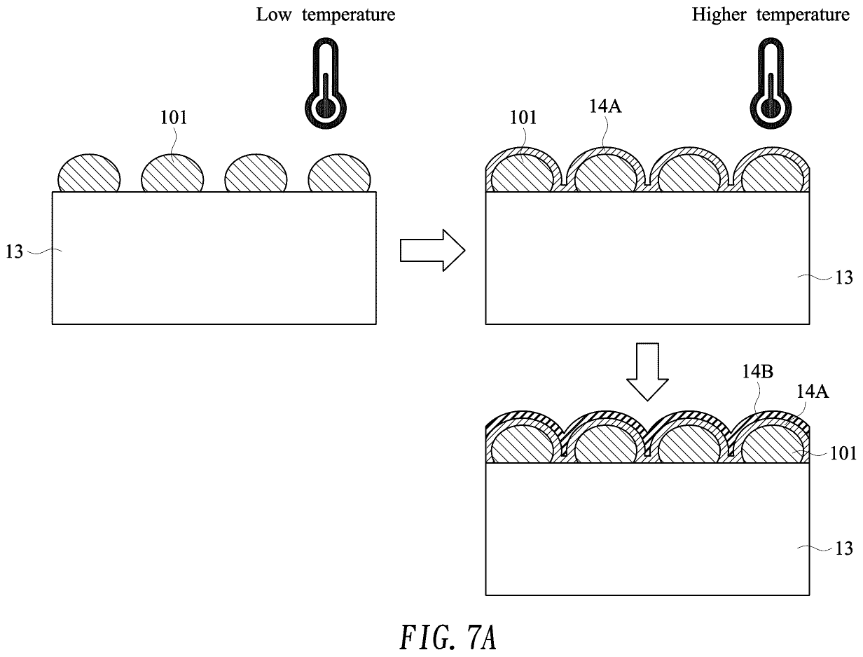

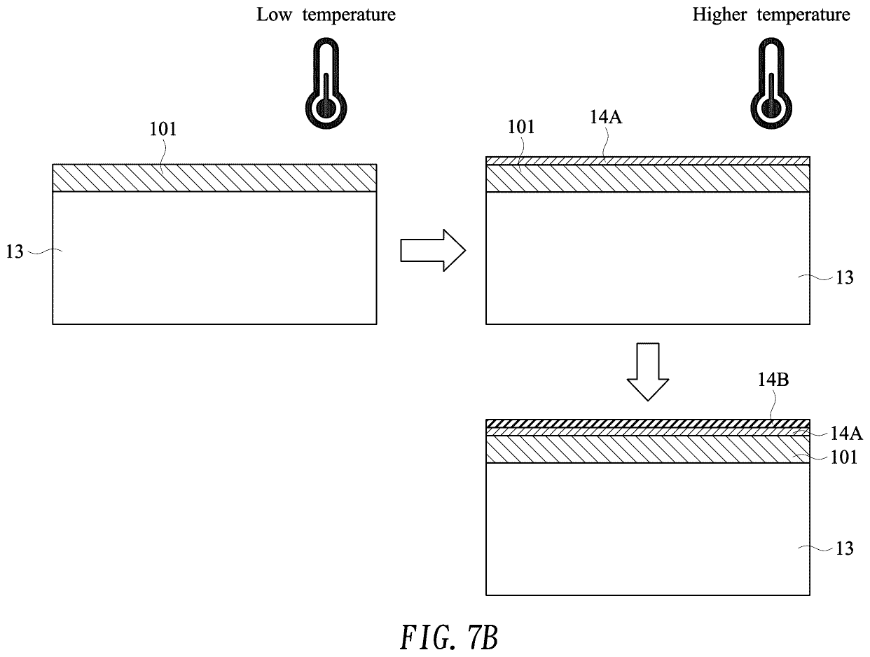

FIGS. 7A and 7B shows a method for depositing a multi-layered passivation layer to cover metal nanoparticles in accordance with an embodiment of the present invention. In which FIG. 7B is more macroscopic than FIG. 7A. Alternatively, in another embodiment, the metal nano-film 10 is a whole layer, and the passivation layer is deposited on the surface of the whole metal nano-film 10. Referring to FIGS. 7A and 7B, the passivation layer can be formed with the following two steps:

### (1) First Step

The first step is to deposit the first passivation layer 14A via a low temperature process, such as PVD, ALD, sol-gel, spin coating, etc., in an oxygen-free environment with temperature precisely controlled less than 100° C. The low temperature deposition ensures that the morphology of the metal nano-film, consisting of metal nanoparticles 101 (or metasurface 102), will not be changed or damaged due to temperature-induced reformation. The physical vapor deposition (PVD) includes E-beam evaporation, RF sputtering, magnetron sputtering, reactive sputtering, high-power impulse magnetron sputtering (HiPIMS), etc. The atomic layer deposition (ALD) includes plasma-enhanced atomic layer deposition (PEALD), pulsed laser-assisted ALD, etc.

The first passivation layer 14A may comprise, but is not limited to, SiO₂, Si₃N₄, ZnO, Al₂O₃, or TiO₂.

### (2) Second Step

The second step is to deposit the second passivation layer 14B via a higher temperature process, such as CVD, PVD, ALD, etc., in an oxygen-free environment with temperature controlled greater than 100° C. The second passivation layer may comprise, but is not limited to, SiO₂, Si₃N₄, ZnO, Al₂O₃, and/or TiO₂.

The physical vapor deposition (PVD) includes E-beam evaporation, RF sputtering, magnetron sputtering, reactive sputtering, high-power impulse magnetron sputtering (HiPIMS), etc.

The chemical vapor deposition (CVD) includes plasma-enhanced CVD (PECVD), atmospheric pressure CVD (APCVD), low-pressure CVD (LPCVD), hybrid physical-chemical vapor deposition (HPCVD), molecular beam epitaxy-CVD (MBE-CVD), etc.

The atomic layer deposition (ALD) includes plasma-enhanced atomic layer deposition (PEALD), pulsed laser-assisted ALD, etc.

The first passivation layer 14A comprises an oxide layer (e.g., SiO₂, Al₂O₃, ZnO, etc.), a nitride layer (e.g., Si₃N₄, AlN, TiN, etc.), or a dielectric layer (e.g., ZnS, Teflon, MgF₂, etc.). The first passivation layer can be deposited using physical vapor deposition (PVD), chemical vapor deposition (CVD), or atomic layer deposition (ALD).

The material of the passivation layer 14 excludes metals, as they could adversely affect the Schottky interface between the metal nano-film and the semiconductor substrate, e.g., silicon.

The second passivation layer 14B comprises one or more oxide layers (e.g., SiO₂, Al₂O₃, ZnO, etc.), one or more nitride layers (e.g., Si₃N₄, AlN, TiN, etc.), and/or one or more dielectric layers with each comprising ZnS, Teflon, or MgF₂.

In some embodiments, the material of the first passivation layer 14A is the same as the material of the second passivation layer 14B. For example, in the first step a first SiO₂ passivation layer is deposited by E-beam then in the second step a second SiO₂ passivation layer is deposited by PECVD. In another example, in the first step a first Si₃N₄ passivation layer is deposited by sputtering then in the second step a second Si₃N₄ passivation layer is deposited by HDPCVD.

In some embodiments, the material of the first passivation layer 14A differs from the material of the second passivation layer 14B. For example, in the first step a first SiO₂ passivation layer is deposited by ALD then in the second step a second ZnS passivation layer is deposited by sputtering. In another example, in the first step a first ZnO passivation layer is deposited by sol-gel then in the second step a second TiO₂ passivation layer is deposited by E-beam.

In some embodiments, in addition to protecting the metal nano-film consisting of metal nanoparticles or a metasurface, the second passivation layer 14B combined with the first passivation layer 14A also serves as an anti-reflection layer or a Bragg mirror comprising alternating high-refractive-index layers and low-refractive-index layers. In one embodiment, the combination of the second passivation layer 14B and the first passivation layer 14A is a double-layer anti-reflection coating including a high-refractive-index layer (the first passivation layer 14A) deposited on the metal and a low-refractive-index layer (the second passivation layer 14B) deposited on the high-refractive-index layer. And the double-layer anti-reflection coating satisfies: n₁<n₂, n1≈(n₀²·nₛ)^{1/3}, n₂≈(n₀·nₛ²)^{1/3}, and d₁=λ₀/4n₁, d₂=λ₀/4n₂, wherein n₂ denotes the refractive-index of the high-refractive-index layer, n₁ denotes the refractive-index of the low-refractive-index layer, nₛ denotes the refractive-index of the metal, no denotes the refractive-index of air, d₁ denotes thickness of the low-refractive-index layer, d₂ denotes thickness of the high-refractive-index layer, and λ₀ denotes the center wavelength of the incident light. In one example, for incident light with center wavelength 550 nm, the high-refractive-index layer is made of Si₃N₄ with thickness of 69 nm, and the low-refractive-index layer is made of SiO₂ with thickness of 94 nm.

In another embodiment, the combination of the first passivation layer 14A and the second passivation layer 14B is a triple anti-reflection coating including a first, a second, and a third-refractive-index layer. The third-refractive-index layer is deposited on the metal, the second-refractive-index layer is deposited on the third-refractive-index layer, and the first-refractive-index layer is deposited on the second-refractive-index layer. And the triple-layer anti-reflection coating satisfies: n₀<n₁<n₂<n₃<nₛ and dᵢ=λ₀/4nᵢ, i=1, 2, or 3. Where n₁, n₂, n₃ respectively denotes the refractive-index of the first, second, and third-refractive-index layer, and d₁, d₂, d₃ respectively denotes the thickness of the first, second, and third-refractive-index layer.

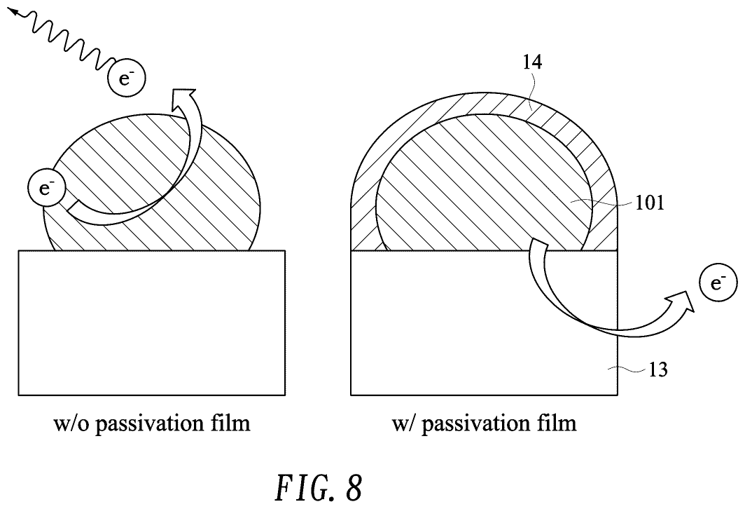

FIG. 8 is schematic view showing a function of the inventive passivation layer. Referring to FIG. 8, the passivation layer composed of one or more dielectric layers (e.g., SiO₂, Si₃N₄, etc.) can prevent current leaking from surface of metal.

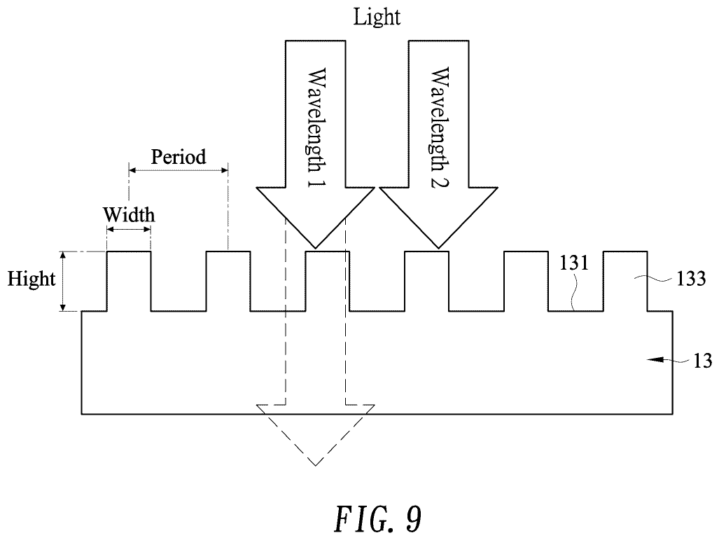

FIG. 9 is schematic side view showing a semiconductor substrate in accordance with an embodiment of this invention. Referring to FIGS. 1 and 9, in some embodiments, the first surface 131 of the semiconductor (e.g., silicon) substrate 13 may include periodic micro/nanostructures 133 to reduce reflectivity of the incident light and/or to induce localized surface plasmon resonance (LSPR) by interaction between the metal nano-film and the incident light. Note that the periodic micro/nanostructures 133 can be applied to all embodiments of the present disclosure. In this document, “periodic micro/nanostructures” refers to “periodic microstructures” and/or “periodic nanostructures.”

Referring to FIG. 9, geometric parameters of the periodic micro/nanostructures 133 are selected to increase absorption in one or more selected wavelengths or wavelength bands of the incident light. The geometric parameters of the periodic micro/nanostructures generally include period, width, and height of the periodic micro/nanostructures.

In some embodiments, the periodic micro/nanostructures 133 may be an inverted pyramid micro/nanostructure array, a pyramid micro/nanostructure array, a micro/nano-cylindrical array, or a micro/nano-grid array.

In some embodiments, the surface of the periodic micro/nanostructures 133 is modified to alter a surface property, e.g., surface area, surface energy, hydrophilicity, and/or roughness, to improve performance and stability of the photodetector.

In one embodiment, the surface of the periodic micro/nanostructures is modified by a physical process, e.g., a plasma etching.

In one embodiment, the surface of the periodic micro/nanostructures is modified by a chemical process, e.g., modified by an etching solution.

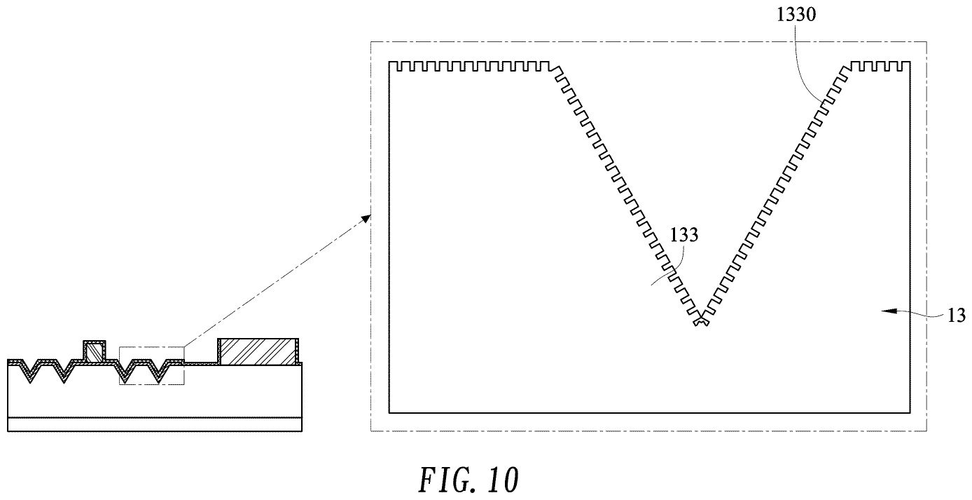

FIG. 10 is a partially enlarged schematic view showing a semiconductor substrate in accordance with an embodiment of this invention. Referring to FIG. 10, in one embodiment, the surface of the periodic micro/nanostructures 133 is modified to form 3D-structures 1330 to increase specific surface area of the periodic micro/nanostructures 133.

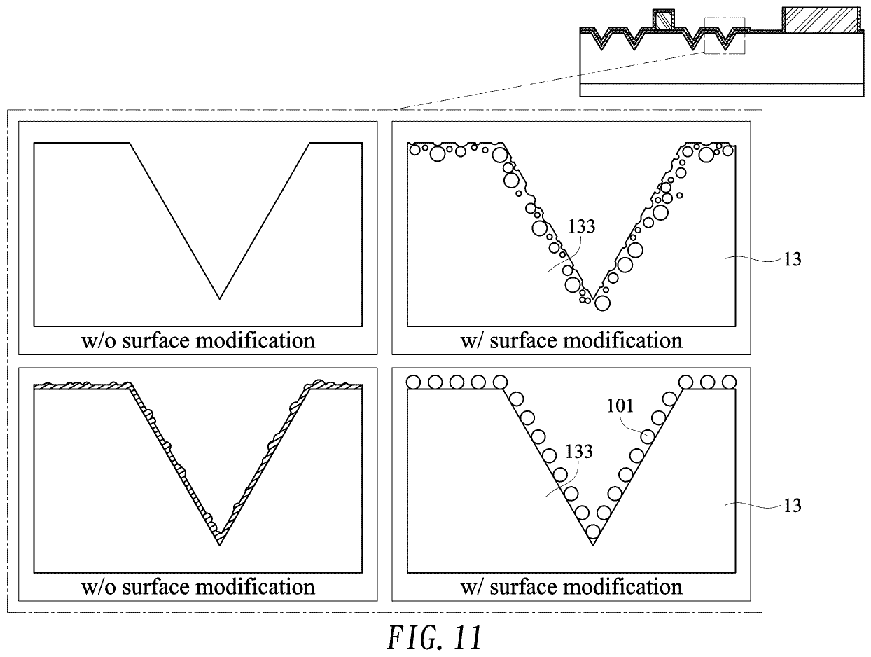

FIG. 11 is a partially enlarged schematic view showing a semiconductor substrate in accordance with an embodiment of this invention.

Referring to FIG. 11, in one embodiment, the surface of the periodic micro/nanostructures 133 is modified to result in a rough surface or a porous surface.

Referring to FIG. 11, in one embodiment, the surface of the periodic micro/nanostructures 133 is modified to alter the surface energy of semiconductor substrate, and hence affect the morphology (e.g., spacing, size, etc.) of subsequently deposited metal nanoparticles 101.

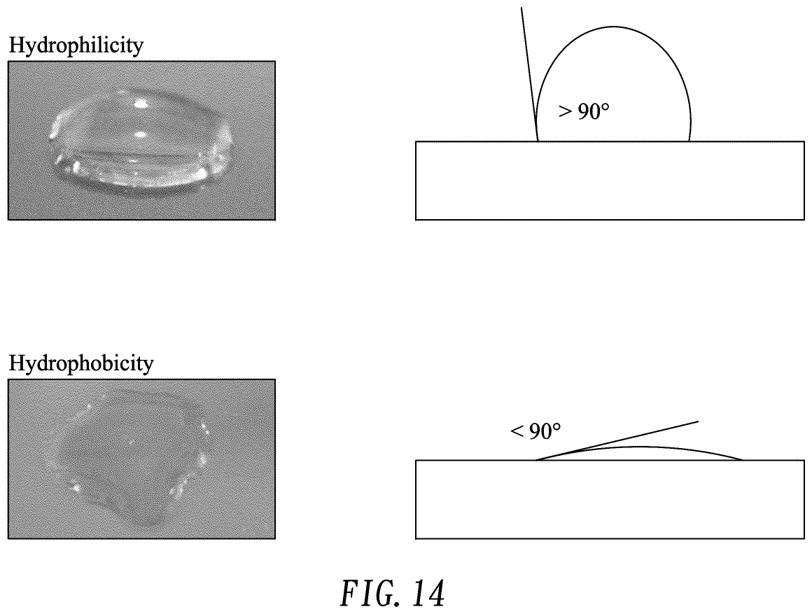

FIG. 14 are photographs and schematic diagrams showing that surfaces (the first surfaces 131 or the surfaces of the periodic micro/nanostructures 133) of two semiconductor substrates are modified into a hydrophobic surface with a water contact angle smaller than 90 degrees and a hydrophilic surface with a water contact angle larger than 90 degrees, respectively.

Although specific embodiments have been illustrated and described, it will be appreciated by those skilled in the art that various modifications may be made without departing from the scope of the present invention, which is intended to be limited solely by the appended claims.

What is claimed is:

1. A photodetector for detecting an incident light, comprising:
a semiconductor substrate having a first surface and a second surface;
a metal nano-film comprising nanoparticles or nanostructures in Schottky contact of the first surface of the semiconductor substrate;
a first electrode in contact of the first surface of the semiconductor substrate;
a second electrode in contact of the second surface of semiconductor substrate; and
a first passivation layer covering the nanoparticles or nanostructures of the metal nano-film.

2. The photodetector according to claim 1, wherein the metal nano-film comprises a first metal nano-film, and the first metal nano-film comprises metal nanoparticles to reduce reflectivity of the incident light and to induce localized surface plasmon resonance (LSPR) by interaction between the metal nanoparticles and the incident light, and wherein the first passivation layer covering the metal nanoparticles and exposed surfaces of the semiconductor substrate between the metal nanoparticles.

3. The photodetector according to claim 2, wherein the metal nanoparticles are formed by an annealing process, and the morphology of the metal nanoparticles is adjusted by one or more parameters of the annealing process.

4. The photodetector according to claim 3, wherein the metal nanoparticles have a height between about 10 nm and about 50 nm.

5. The photodetector according to claim 3, wherein the metal nanoparticles have a width between about 5 nm and about 500 nm.

6. The photodetector according to claim 3, wherein a spacing between the metal nanoparticles is between about 0.5 nm and about 50 nm.

7. The photodetector according to claim 1, wherein the metal nano-film a first metal nano-film, and the first metal nano-film comprises a metasurface composed of a plasmonic nanostructure array with sub-wavelength periodicity for inducing localized surface plasmon resonance (LSPR), and wherein the first passivation layer covers the metasurface.

8. The photodetector according to claim 1, wherein the first passivation layer comprises an oxide layer, a nitride layer, or a dielectric layer comprising ZnS, Teflon, or MgF₂.

9. The photodetector according to claim 8, further comprising a second passivation layer in contact of the first passivation layer, and wherein the second passivation layer comprises one or more oxide layers, one or more nitride layers, and/or one or more dielectric layers with each comprising ZnS, Teflon, or MgF₂.

10. The photodetector according to claim 9, wherein the material of the first passivation layer differs from the material of the second passivation layer.

11. The photodetector according to claim 9, wherein the material of the first passivation layer is the same as the material of the second passivation layer.

12. The photodetector according to claim 8, further comprising a second passivation layer in contact of the first passivation layer, and wherein the second passivation layer combined with the first passivation layer is used as an anti-reflection layer or a Bragg mirror comprising alternating high-refractive-index layers and low-refractive-index layers.

13. The photodetector according to claim 1, wherein the first surface of the semiconductor substrate comprises periodic micro/nanostructures to reduce reflectivity of the incident light and/or induce localized surface plasmon resonance (LSPR) by interaction between the metal nano-film and the incident light, and wherein geometric parameters of the periodic micro/nanostructures are selected to increase absorption in one or more selected wavelengths or wavelength bands of the incident light.

14. The photodetector according to claim 13, wherein a surface of the periodic micro/nanostructures is modified to alter a surface property comprising surface area, surface energy, hydrophilicity, and/or roughness.

15. The photodetector according to claim 13, wherein the periodic micro/nanostructures comprise an inverted pyramid micro/nanostructure array, a pyramid micro/nanostructure array, a micro/nano-cylindrical array, or a micro/nano-grid array.

16. The photodetector according to claim 1, wherein the metal nano-film comprises a first metal nano-film deposited on the first surface of the semiconductor substrate and a second metal nano-film deposited on the first metal nano-film, and the second metal nano-film comprises a metasurface composed of a plasmonic nanostructure array with sub-wavelength periodicity for inducing surface plasmon resonance (LSPR), and wherein the first passivation layer covers the metasurface.

17. The photodetector according to claim 16, wherein the plasmonic nanostructure array comprises a grid array, a block array, a cross array, or an inverted cross array, and wherein one or more resonant wavelengths of the surface plasmon resonance are determined by one or more geometric parameters of the plasmonic nanostructure array.

18. The photodetector according to claim 17, wherein the one or more geometric parameters comprises a width, a length, a period, and a thickness of patterns composing the plasmonic nanostructure array.

19. The photodetector according to claim 18, wherein the incident light comprises mid-wave infrared (MWIR) light, and the thickness of patterns composing the plasmonic nanostructure array is between about 200 nm and about 600 nm.

20. The photodetector according to claim 19, wherein the plasmonic nanostructure array comprises the cross array, and wherein the width is between about 0.2 μm and about 2.5 μm, the length is between about 0.8 μm and about 3.5 μm, and the period is between about 1.5 μm and about 4.0 μm.

21. The photodetector according to claim 19, wherein the plasmonic nanostructure array comprises the inverted cross array, and wherein the width is between about 1.0 μm and about 4.0 μm, the length is between about 0.2 μm and about 6.0 μm, and the period is between about 1.5 μm and about 8.0 μm.

22. The photodetector according to claim 19, wherein the plasmonic nanostructure array comprises the block array, and wherein the width is between about 1.0 μm and about 6.0 μm, and the period is between about 1.5 μm and about 8.0 μm.

23. The photodetector according to claim 19, wherein the plasmonic nanostructure array comprises the grid array, and wherein the width is between about 0.8 μm and about 5.0 μm, and the period is between about 1.5 μm and about 8.0 μm.

24. The photodetector according to claim 16, wherein the first metal-nano film and the metasurface are made of different metals.

25. The photodetector according to claim 16, wherein the first metal-nano film and the metasurface are made of a same metal.
